(19) United States
(12) Patent Application Publication
(10) Pub. No.: US 2012/0002420 A1
(43) Pub. Date: Jan. 5, 2012

(54) LED module, LED package, and wiring substrate and method of making same

(75) Inventors: Noboru Imai, Takahagi (JP); Masahiro Noguchi, Hitachi (JP); Fumiya Isaka, Hitachi (JP); Akiji Shibata, Hitachi (JP); Yuzuru Ashidate, Hitachi (JP); Aki Suzuki, Hitachi (JP)

(73) Assignee: HITACHI CABLE, LTD., Tokyo (JP)

(21) Appl. No.: 13/067,725

(22) Filed: Jun. 22, 2011

(30) Foreign Application Priority Data
Jul. 1, 2010 (JP) 2010-151425
Jan. 21, 2011 (JP) 2011-010341

(51) Int. Cl. F21S 4/00; F21V 21/00; H01K 3/10; H05K 1/09

(52) U.S. Cl. 362/249.02; 174/257; 362/382; 29/852

(57) ABSTRACT

An LED module includes an electrical insulation material including a first surface having a total reflectivity of not less than 80% with respect to light with a wavelength of 450 nm, a via hole penetrating through the electrical insulation material, a wiring pattern on a second surface of the electrical insulation material, a metal filler formed in the via hole and electrically connected to the wiring pattern, and an LED chip bonded to a surface of the metal filler on the first surface of the electrical insulation material, and sealed with a resin.

The present application is based on Japanese patent application Nos. 2010-151425, 2011-010341 filed on Jul. 1, 2010 and Jan. 21, 2011, respectively, the entire contents of which are incorporated herein by reference.

### BACKGROUND OF THE INVENTION

1. Field of the Invention

This invention relates to an LED module, an LED package, and a wiring substrate used for the LED module and the LED package, and a method of making the wiring substrate.

2. Description of the Related Art

In recent years, for the purpose of energy saving and CO2 emission reduction, products using an LED chip as a light source increase that include a mobile device with an LCD display such as a cellular phone and a laptop computer, an LCD television called “LED-TV” with an LED backlight, and an LED bulb using an LED module as a light source.

These products have an LED module or an LED package installed therein that includes an LED chip mounted on a wiring substrate such as 1) a glass epoxy substrate, 2) aluminum base substrate, 3) ceramic substrate. Also, they may have an LED package installed therein that includes an LED chip mounted on a lead frame and molded by a white molding resin.

As the LED chip for the LED module or the LED package, a GaN based blue LED chip is generally used such that it emits white light by being sealed with a sealing material with a phosphor mixed therein for wavelength-converting blue light into white light. The GaN based blue LED chip needs to have a small size, e.g., 0.25 mm×0.35 mm square so as to reduce the dispersion in the emission characteristics.

FIG. 12 shows an example of a conventional LED module. The LED module is constructed such that an adhesive layer 2 is formed on one surface of a substrate 1 such as the above substrates 1) to 3), a copper foil is patterned thereon to form a wiring pattern 5, an LED chip 7 is mounted on the wiring pattern 5, the LED chip 7 is bonded to the wiring pattern 5 by using wires 8, and the LED chip 7 is sealed with a sealing material 9.

Here, the LED chip mounted on the LED module or the LED package may generate a large amount of heat. Since the heat generated affects the life or the luminescent efficiency of the product, various measures for dissipating the heat have been researched.

The related prior art to the invention may be JP-A-2005-235778 at paragraphs 0005 to 0012 or JP-A-2009-054860 at claims 1 and 5.

### SUMMARY OF THE INVENTION

Since the wiring substrate using the above substrates 1) to 3) or the lead frame generally has a thickness of more than 200 μm, it may obstruct the low-profile LED module or LED package.

In order to prevent the overheat of the LED chip, it is generally important to accelerate the heat transfer from the LED chip mounting surface to the back surface of the wiring substrate. Therefore, the thickness of the wiring substrate needs to be considered.

When a thick substrate is used, it is desired to provide a via or a heat sink for heat transfer. FIG. 13 shows an example of a conventional LED module using a heat sink. The module is constructed such that the wiring substrate in FIG. 12 is used, a via hole 4 is formed just under the LED chip 7, a metal filled part 6 is formed by filling a metal in the via hole 4, and the heat sink H is formed on the opposite side of the wiring pattern 5. In general, in making such an LED module or LED package, a double-sided wiring substrate is used or a thick heat sink is integrated to make an LED package. This use may be limited to the case that the LED chip is used at a large current for providing a lighter and more compact product or reducing the manufacturing cost.

Also, in order to utilize light emitted from the LED chip as much as possible, it is important to have the light reflect from the substrate side. In general, except the case of using a white ceramic substrate, a wiring substrate is constructed such that silver plating is formed on the wiring surface exposed for bonding, and the substrate surface including the wiring is printed with a white resin or covered with a white resin extruded and mold.

In this structure, the silver plating is difficult to control in the appearance such as evenness or color tone when forming the silver plating. Even after completing the LED package, it is subjected to color change due to sulfidation etc., so that a light reflectivity thereof may lower.

The printable white resin has to be formed a fine aperture for a small LED chip bonding or wire bonding due to the fineness of the LED chip, so that such a fine aperture may cause a problem in the accuracy of the aperture position or shape upon the printing of the fine aperture. Also, there is another problem that the printable and photolithography-processable white resin is a little lower in heat resistance than the printable white resin.

On the other hand, there is another problem that the extrudable and moldable white resin is low in utilization efficiency when the volume of the extrusion mold is small as in the LED package.

Accordingly, it is an object of the invention to provide an LED module, an LED package, a wiring substrate and a method of making the wiring substrate that are 1) excellent in heat dissipation efficiency even with a single-sided wiring substrate, 2) low-profile, 3) with a wiring pattern unlikely to affect the reflection of a light emitted from the LED chip, and 4) not always dependent on the silver plating formed on the wiring pattern, especially suited for small-size LED chips.

(1) According to one embodiment of the invention, an LED module comprises:

an electrical insulation material comprising a first surface having a total reflectivity of not less than 80% with respect to light with a wavelength of 450 nm;
a via hole penetrating through the electrical insulation material;

a wiring pattern on a second surface of the electrical insulation material;

a metal filler formed in the via hole and electrically connected to the wiring pattern; and

an LED chip bonded to a surface of the metal filler on the first surface of the electrical insulation material, and sealed with a resin.

### (2) According to Another Embodiment of the Invention, a Wiring Substrate Comprises:

an electrical insulation material comprising a first surface having a total reflectivity of not less than 80% with respect to light with a wavelength of 450 nm;

a via hole penetrating through the electrical insulation material;

a copper wiring pattern on a second surface of the electrical insulation material; and

a metal filler formed in the via hole and electrically connected to the wiring pattern,

wherein the metal filler is exposed from the electrical insulation material on the first surface of the electrical insulation material.

In the above embodiment (1) or (2) of the invention, the following modifications and changes can be made.

(i) The first surface of the electrical insulation material is white in color.

(ii) The electrical insulation material further comprises a white insulation material, a base material and an adhesive material, or a white base material and an adhesive material.

(iii) The base material or the white base material comprises one resin of polyimide, polyamide-imide, polyethylene-naphthalate, epoxy and aramid.

(iv) The base material or the white base material has a thickness of not less than 4 μm and not more than 75 μm.

(v) The metal base material comprises a flat portion with a diameter of not less than 0.1 mm at a top thereof.

(vi) The metal base material is formed by copper electroplating.

(vii) The metal base material comprises a plating on a top thereof, and the plating comprises one of gold, silver, palladium, nickel and tin.

(viii) The metal base material comprises a protrusion from the first surface of the electrical insulation material, and the protrusion comprises a cross sectional portion greater than the via hole.

### (3) According to Another Embodiment of the Invention, an LED Package Comprises:

the LED module according to the embodiment (1) and segmented in unit of one or more of the LED chip.

### (4) According to Another Embodiment of the Invention, a Method of Making the Wiring Substrate According to the Embodiment (2) Comprises:

forming the via hole in the electrical insulation material;

laminating a metal foil on the second surface of the electrical insulation material; and

filling the metal filler in the via hole through the first surface of the electrical insulation material.

### Points of the Invention

According to one embodiment of the invention, an LED module is constructed such that an LED chip is mounted on the surface of a buried plating (i.e., a heat dissipation metal filler formed in a via hole) opposite the mounting surface (on the side of a wiring pattern) of a conventional LED chip. In other words, in the embodiment of the invention, there is provided a wiring pattern on the side of the mounting surface of the LED chip. Therefore, it is not necessary to limit the kind of plating formed on the wiring pattern to silver though the wiring pattern is conventionally silver-plated to enhance the reflection of light from the LED chip on the wiring pattern.

### BRIEF DESCRIPTION OF THE DRAWINGS

The preferred embodiments according to the invention will be explained below referring to the drawings, wherein:

FIG. 1 is a cross sectional view showing one unit of an LED module in one embodiment of the invention;

FIGS. 2A to 2E are cross sectional views showing a method of making a wiring substrate in one embodiment of the invention;

FIGS. 3A to 3C show one unit of an LED module in one embodiment of the invention, wherein FIG. 3A is a plan view showing a wiring substrate before mounting an LED chip, FIG. 3B is a top view showing a wiring substrate after mounting an LED chip in a modification that a heat dissipation metal filler 6a is formed rectangular, and FIG. 3C is a bottom view showing the wiring substrate in FIG. 3B;

FIGS. 4A to 4C show an LED module in one embodiment of the invention, wherein FIG. 4A is a top view thereof viewed from the mounting side of an LED chip,

FIG. 4B is a bottom view thereof, and FIG. 4C is a bottom view showing the LED module that feeding wires are covered with a protecting film;

FIGS. 5A to 5B are cross sectional views showing one unit of an LED module in one embodiment of the invention;

FIGS. 6A to 6B show one unit of an LED module in one embodiment of the invention, wherein FIG. 6A is a top view thereof viewed from the mounting side of an LED chip, FIG. 6B is a bottom view thereof;

FIGS. 7A to 7D show one unit of an LED module in one embodiment of the invention, wherein FIG. 7A is a cross sectional view thereof, FIG. 7B is a bottom view thereof, and FIGS. 7C and 7D are cross sectional views showing modifications of the LED module in FIG. 7A;

FIGS. 8A to 8B show one unit of an LED module in one embodiment of the invention, wherein FIG. 8A is a cross sectional view thereof and FIG. 8B is a top view thereof;

FIGS. 9A to 9B show one unit of an LED module in one embodiment of the invention, wherein FIG. 9A is a cross sectional view thereof and FIG. 9B is a top view thereof;

FIGS. 10A to 10C show one unit of an LED module in one embodiment of the invention, wherein FIG. 10A is a cross sectional view thereof, and FIGS. 10B and 10C are cross sectional views showing modifications of the LED module in FIG. 10A;

FIGS. 11A to 11B show one unit of an LED module in one embodiment of the invention, wherein FIG. 11A is a cross sectional view thereof, and FIG. 11B is a cross sectional view showing a modification of the LED module in FIG. 11A;

FIG. 12 is a cross sectional view showing one unit of a conventional LED module with a general single-sided substrate;

FIG. 13 is a cross sectional view showing one unit of a conventional LED module with a general double-sided substrate; and

FIGS. 14A to 14F show one unit of an LED module in a sub-embodiment of the invention, wherein the LED module is made by providing a buried plating with a general single-sided substrate, FIGS. 14A to 14E are cross sectional views showing a method of making a wiring substrate for the LED module, and FIG. 14F is a cross sectional view showing the completed LED module.

### DETAILED DESCRIPTION OF THE PREFERRED EMBODIMENTS

The preferred embodiments of the invention will be explained bellow.

### First Embodiment

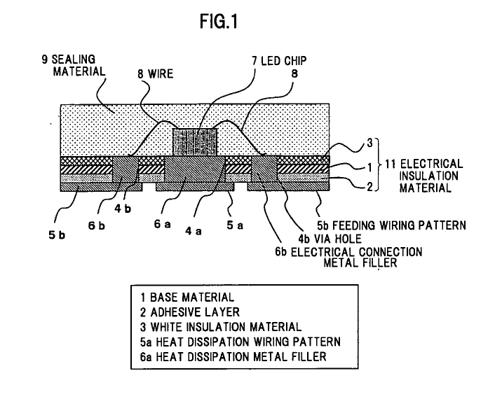

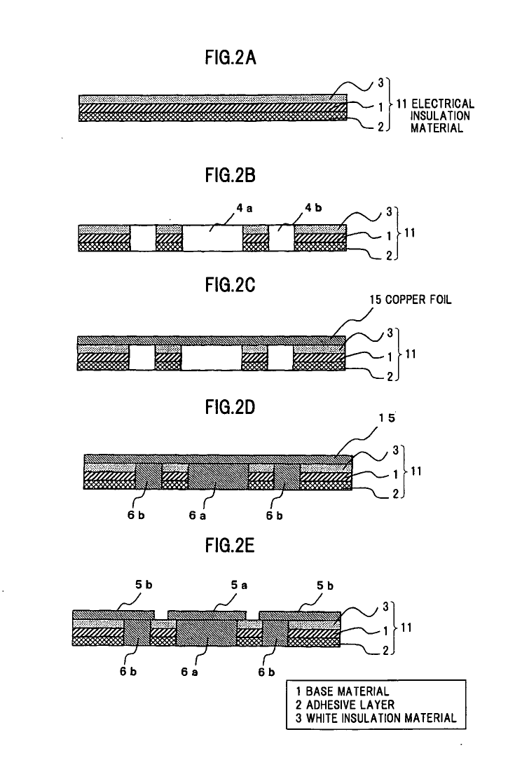

FIG. 1 is a cross sectional view showing one unit of an LED module in one embodiment of the invention. FIG. 2A to 2E are cross sectional views showing a method of making a wiring substrate in one embodiment of the invention. Although the method of the embodiment is exemplarily explained below in reference to a method of TAB (tape automated bonding) substrate, a method of making a rigid substrate or a flexible substrate etc. may also apply to the invention.

The LED module and wiring substrate in the embodiment are, as shown in FIG. 1, comprised of an electrical insulation material 11, via holes 4a, 4b penetrating through the electrical insulation material 11, a heat dissipation wiring pattern 5a, a feeding wiring pattern 5b, a heat dissipation metal filler 6a electrically connected to a wiring pattern formed in the via holes 4a, 4b, and a electrical connection metal filler 6b. An LED chip 7 is bonded on a first surface of the electrical insulation material 11 and to the tip of the heat dissipation metal filler 6a and the electrical connection metal filler 6b by using a wire 8, and resin-sealed with a sealing material 9.

The electrical insulation material 11 of the embodiment is constructed such that an adhesive layer 2 is attached to one surface of the base material 1, and a white insulation material 3 is attached to the opposite surface. However, when the base material 1 has a reflectivity of not less than 80% and is white, the white insulation material 3 may be omitted. In other words, the material as an uppermost layer on the mounting surface of the LED chip 7 may have a high reflectivity (not less than 80%) and be white.

The base material 1 is desirably a film including one resin of polyimide, polyamide-imide, polyethylene-naphthalate, epoxy and aramid. The electrical insulation material 11 can be produced by coating the base material 1 with the white insulation material 3 and then laminating or coating the thermosetting adhesive layer 2. Here, for example, when a film including aramid with a high elasticity as a main component is used for the base material 1, even the base material 1 as thin as 4 μm can be produced. Although the thermosetting adhesive material may be chosen from an adhesive material for TAB or flexible substrate and a coverlay adhesive material, it is preferably an epoxy adhesive material in terms of electrical insulation or heat resistance. For example, the manufacturer thereof may be TOMOEGAWA Co., Ltd., TORAY Industries, Inc., Arisawa manufacturing Co., Ltd. The material for the electrical insulation material 11 may be, e.g., white coated polyimide film from Mitsui Chemicals, Inc. or TOYOBO Co., Ltd. or a white coverlay coated with an adhesive material from Arisawa manufacturing Co., Ltd. The electrical insulation material 11 may be formed with a slit (not shown) at a width workable in roll form for adapting for a so-called roll-to-roll system to be flown in the TAB production process.

The process for making the wiring substrate will be described below referring to FIG. 2A to 2E.

First, as shown in FIG. 2A, the electrical insulation material 11 is provided that has the white insulation material 3 at one side of the base material 1 and the adhesive layer 2 at the opposite side thereof.

As shown in FIG. 2B, the via holes 4a, 4b are formed in the electrical insulation material 11 by pressing the electrical insulation material 11. Here, if necessary, a sprocket hole (not shown) or an alignment hole (not shown) may be formed therein. The via holes 4a, 4b may be formed by the other known method than the pressing.

As shown in FIG. 2C, a copper foil 15 is laminated on the adhesive layer 2 of the electrical insulation material 11. The copper foil 15 is generally preferred to be a thickness of about 18 to 70 μm, but not limited to the thickness. For the lamination, it is preferred to use a roll laminator workable under ordinary pressure or reduced pressure. The conditions of the lamination may be chosen on the basis of the reference conditions shown by the manufactures of the adhesive material. In many thermosetting adhesive materials, post-curing is generally conducted at a high temperature of 150° C. or more after completing the lamination. This can be also determined on the basis of the reference conditions shown by the manufactures of the adhesive material.

As shown in FIG. 2D, the heat dissipation metal filler 6a and the electrical connection metal filler 6b are formed by providing the buried plating in the via holes 4a, 4b by electric copper plating. The method of the buried plating may use the known techniques disclosed in JP-A-2003-124264 etc. For example, after masking with a masking tape (not shown) the surface opposite the surface forming the via holes 4a, 4b of the copper foil 15, copper plating is conducted on the copper foil 15 exposed in the via holes 4a, 4b to form the heat dissipation metal filler 6a and the electrical connection metal filler 6b. Here, by changing the kind of copper plating solution and the plating conditions, the tip of the heat dissipation metal filler 6a and the electrical connection metal filler 6b can be formed convex, concave or flat. Also, the height of the heat dissipation metal filler 6a and the electrical connection metal filler 6b can be arbitrarily controlled by the plating conditions (mainly the plating time). In addition, depending on the plating solution and the plating conditions, the diameter of the tip of the metal filler can be greater than that of the via holes 4a, 4b. Meanwhile, the copper plating solution and the usage thereof can be available from the manufacturers of the copper solution such as EBARA-UDYLITE Co., Ltd. and Atotech Deutschland GmbH.

As shown in FIG. 2E, the heat dissipation wiring pattern 5a and the feeding wiring pattern 5b are formed by pattern the copper foil 15. The patterning of the heat dissipation wiring pattern 5a and the feeding wiring pattern 5b is conducted as in the process of the known photolithography such that the masking tape on the copper foil 15 used in forming the heat dissipation wiring pattern 5a and the feeding wiring pattern 5b is removed, an etching resist is coated thereon, the etching resist is exposed and developed to etch the copper foil 15, and the etching resist is removed. Instead of the etching resist, a dry film may be used. In pattern the copper foil 15, the surface of the buried plating is desirably prevented from the etching solution etc. by attaching the masking tape or coating a lining material thereon.

Then, if necessary, on the exposed surface of the heat dissipation metal filler 6a and the electrical connection metal filler 6b is formed a plating (not shown) including one metal of gold, silver, palladium, nickel, and tin. If the masking tape is attached on the buried plating at the previous step, the plating is conducted after the masking tape is removed. Here, the pattern surface of the copper foil and the surface of the buried plating may be alternately masked to have different platings, or the same plating may be formed thereon. In order to reduce the area of the plating, the plating may be conducted after the unnecessary part of the pattern surface of the copper foil is previously covered with a resist or a coverlay.

As produced above, the wiring substrate for the LED module and LED package is completed in the roll form.

A conventional TAB is, as shown in FIG. 12, constructed such that the LED chip 7 is mounted on the side of the wiring pattern 5. By contrast, as shown in FIG. 1, the LED chip 7 of the invention is mounted on the surface of the buried plating (i.e., the heat dissipation metal filler 6a) opposite the mounting surface of the conventional LED chip 7.

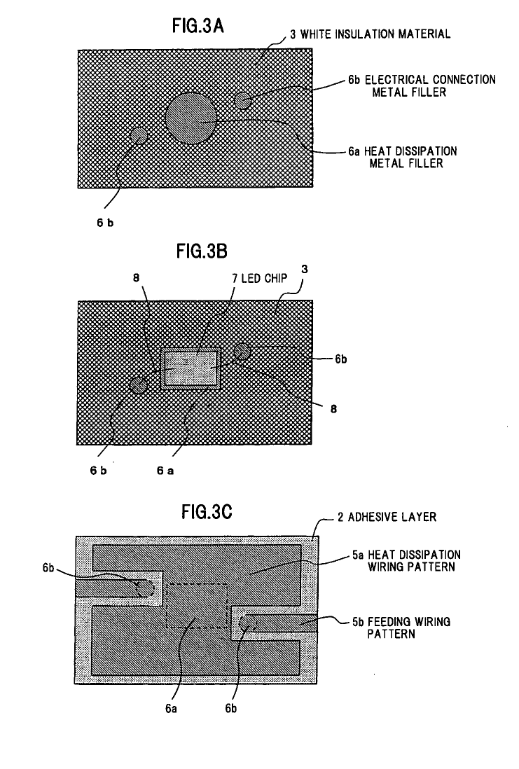

Focusing on the pattern of one unit of the wiring substrate thus completed, as shown in FIG. 3A, the appearance is such that only the top end of the heat dissipation metal filler 6a and the electrical connection metal filler 6b is seen in the white coating surface (i.e., the white insulation material 3 or white base material 1). By modifying the dimension or shape of the heat dissipation metal filler 6a and the electrical connection metal filler 6b, as shown in FIG. 3B, the LED chip 7—mounted surface of the heat dissipation metal filler 6a may be reduced to be slightly larger than the LED chip 7 when viewed from the emission surface. Thus, it is not necessary to limit the kind of plating to silver in terms of light reflection.

The wiring pattern on the opposite side may be made such that the feeding wiring pattern 5b has a cross sectional area needed to the feeding as shown in FIG. 3C. The other pattern may be made such that the heat dissipation wiring pattern 5a has a large area while being directly connected to the heat dissipation metal filler 6a in the via hole 4a and electrically isolated from the feeding wiring pattern 5b.

For example, where the electrical insulation material is comprised of 20 μm thick white coating layer, 10 μm thick base material and 10 μm adhesive layer, the heat dissipation wiring pattern with an arbitrary thickness can be formed connecting to the metal filler as low as 40 μm in height. When these are of copper, the wiring substrate can be low in thermal resistance by using the high thermal conductivity of copper.

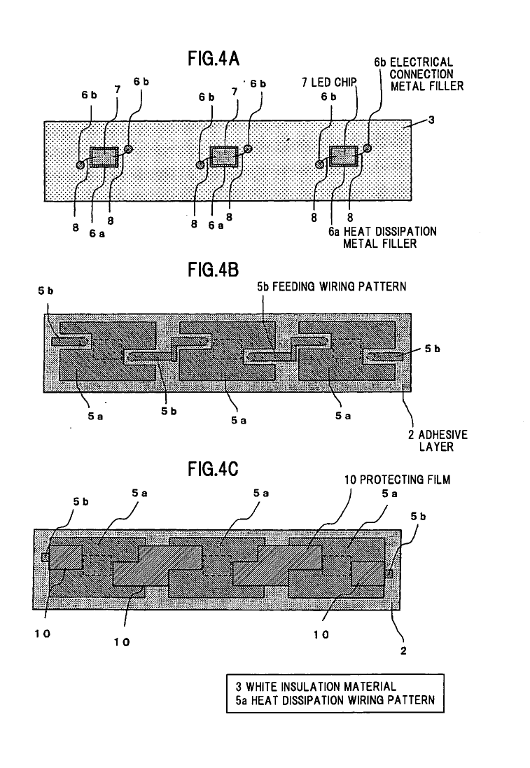

FIG. 4A shows the white coating surface of an LED module with three in-line patterns. Here, although not shown, the image of the wiring substrate is obtained when no LED chip is mounted thereon. As mentioned above, there is the big feature that only the top surface of the buried platings is seen on the white coating surface at the time of the wiring substrate.

FIG. 4B shows the back surface of the LED module. There is the feature that the area of the heat dissipation wiring pattern 5a for the LED chip 7 can be larger than that of the feeding wiring pattern 5b for the LED chip 7. For example, as shown in FIG. 4C, when the feeding wiring pattern 5b is covered with a protecting film 10 such as a resist and a coverlay, only the heat dissipation wiring pattern 5a can be exposed. Therefore, the heat dissipation wiring pattern 5a can be attached to another heat dissipator through a sticky or adhesive material (not shown) with a thermal conductivity higher than the protecting film. Further, when the heat dissipator is provided with a concave portion for canceling the thickness of the resist or coverlay, it can be attached thereto with the thin sticky or adhesive material. The adhesive material may be a solder.

Although not shown, the method of mounting a GaN based blue LED chip on the above wiring substrate will be described below.

First, an LED chip being mounted on a wafer ring or tray is provided and die-bonded by using an LED die bonder. In general, a die bonding material may be a silicone based material. However, when the die bonder has no coating mechanism, the die bonding material is coated on the tip of the metal filler to be die-bonded before die-bonding.

Meanwhile, if the reel-form wiring substrate is difficult to set in the die-bonder, it may be cut into a suitable length and attached to a rectangular metal frame like an outer frame of a lead frame so as to be flown as a pseudo lead frame.

After the die-bonding, the die bonding material is cured. In general, the conditions are at 150° C. for about 1 hour but may be based on a reference value of the manufacturer of the die bonding material.

Then, plasma cleaning is conducted under reduced pressure. Here, a mixed gas of argon and oxygen is generally used. It is used to clean the bonding pad of the LED chip polluted by gas generated in curing the die bonding material.

Then, the wire-bonding between the LED chip and the feeding metal filler is conducted by a wire bonder. For example, a bump is formed at the LED chip by the wire, and a first bonding to the metal filler and a second bonding to the bump on the LED chip are conducted. Thereby, the resistance of heat cycle test can be enhanced.

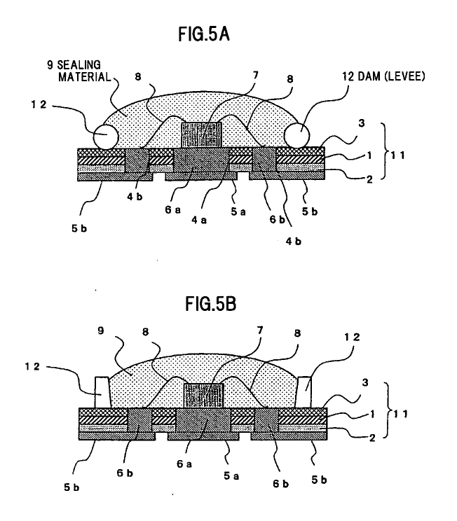

In a modification, a dam may be formed in each LED chip. FIGS. 5A and 5B are cross sectional views showing the modification. As shown, a GaN based white LED module can be produced such that a dam 12 for sealing resin is formed by attaching to the periphery of the LED chip 7 another resin or metal sheet with an opening for filling and damming the sealing material 9 in the dam 12, and filling and sealing the sealing material 9 with a phosphor mixed therein for converting light from the blue LED into white light. The LED module can be segmented into an LED package. The dam 12 for the sealing material 9 may be also formed by drawing sequentially the lines of the white silicone resin by a dispenser. The dam 12 can have the function of a reflection plate by reckoning with the reflectivity and shape. The dam 12 may be formed for plural LED chips or each LED chip.

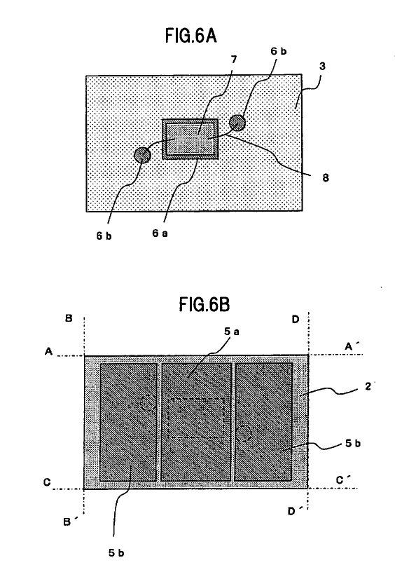

The method of segmenting into the LED package may be, e.g., press-cutting by a cutter such as a Thomson type die cutter.

Where electroless plating is made to form the wiring pattern of the back surface of the LED module and the LED package, as shown in FIGS. 6A and 6B, the wiring pattern can be formed such that the copper pattern does not cross the outer part (i.e., edges defined by line A-A′, line B-B′, line C-C′, and line D-D′ as shown in FIGS. 6A and 6B) to be press-cut by the cutter. Therefore, the burr of the wiring pattern or the falling of a metal burr can be prevented perfectly. The life of the thin cutter can be extended.

### Second Embodiment

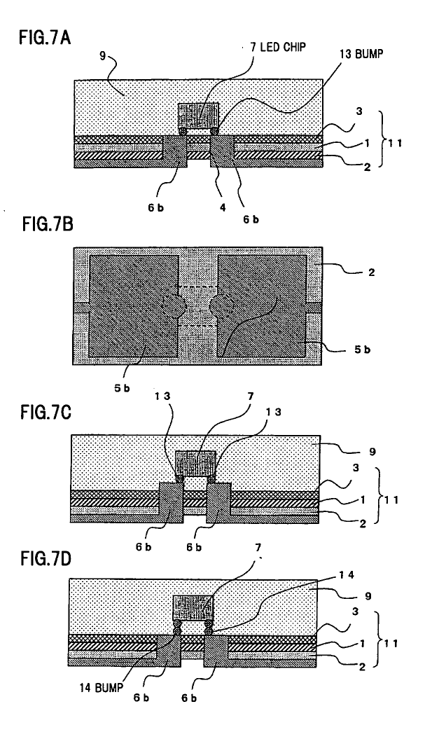

FIGS. 7A to 7D show another embodiment of the invention. FIG. 7A is a cross sectional view showing one unit of an LED module using an LED chip capable of being flip-chip-mounted. FIG. 7B is a bottom view showing an example of a back pattern thereof.

The second embodiment is constructed such that the electrical connection metal filler 6b is formed in a via hole 4 of the electrical insulation material 11, and a bump 13 mounted on the LED chip 7 is directly electrically connected to the electrical connection metal filler 6b by using a flip-chip structure.

As shown in FIG. 7C, the electrical connection metal filler 6b of the via hole 4 may be higher than the surface of the electrical insulation material 11. Thereby, the sealing material becomes easy to fill without voids.

As shown in FIG. 7D, in order to facilitate the flip chip mounting (i.e., in order to secure the electrical connection between the bump 13 and the electrical connection metal filler 6b to reduce the damage of the LED chip 7), a bump 14 of gold etc. may be previously formed on the electrical connection metal filler 6b. The bump 14 can be easily made by a wire bonder.

### Third Embodiment

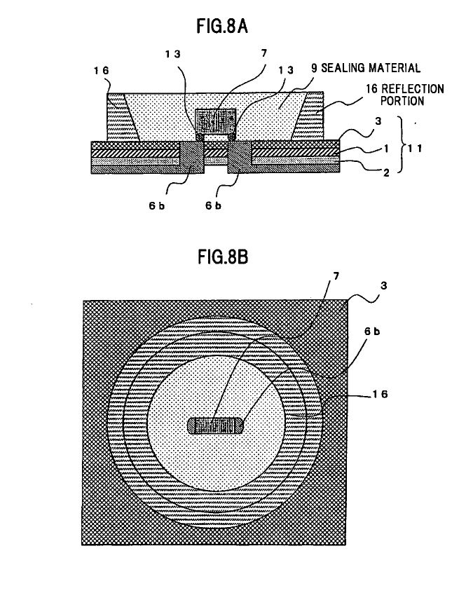

FIGS. 8A and 8B show another embodiment of the invention. The third embodiment is constructed such that, in the second embodiment, a reflection portion 16 is formed molded with a white resin on the electrical insulation material 11, and the sealing material 9 is filled inside the reflection portion 16. FIG. 8A is a cross sectional view of one unit of the LED module and FIG. 8B is a top view thereof. In this embodiment, the simplest method of attaching the reflection portion 16 may be using a white sticky tape (not shown).

In FIG. 8A, the LED chip 7 is flip-chip mounted. As a matter of course, the LED chip 7 may be wire-bonded.

### Fourth Embodiment

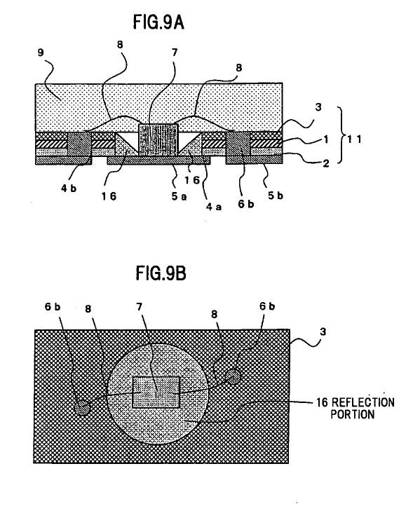

FIGS. 9A and 9B show another embodiment of the invention. The fourth embodiment is constructed such that, as shown in FIG. 9A, the thickness of the electrical insulation material 11 is less than the thickness of the LED chip 7. In the embodiment, the reflection portion 16 may be formed by die-bonding the LED chip 7 while removing or reducing the heat dissipation metal filler 6a in the via hole 4a and then potting the white filling material (e.g., white resist) around the LED chip 7. In this embodiment, the thermal connection distance can be also reduced that is defined between the bottom of the LED chip 7 and the heat dissipation wiring pattern 5a.

### Fifth Embodiment

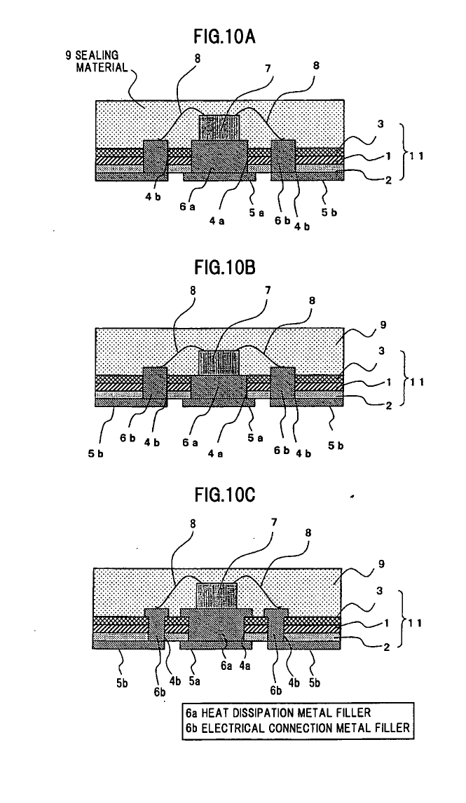

FIGS. 10A to 10C show another embodiment of the invention. The fifth embodiment is constructed such that, although described earlier, as shown in FIG. 10A, the heat dissipation metal filler 6a and the electrical connection metal filler 6b is higher than the surface of the electrical insulation material 11 by, e.g., increasing the time of the buried plating. By the protruded metal filler, an anchor effect can be obtained that restricts the movement of the soft sealing material 9.

As shown in FIG. 10B, the height of the electrical connection metal filler 6b for current feeding may be higher than the surface on which the LED chip 7 is die-bonded or mounted. Thereby, the necessary length of the bonding wires can be reduced and the anchor effect for the soft sealing material 9 can be enhanced.

As shown in FIG. 10C, the tip portion of the heat dissipation metal filler 6a and the electrical connection metal filler 6b may be wider than the diameter of the via holes 4a, 4b by changing the copper plating solution or plating conditions. Thereby, the anchor effect for the soft sealing material 9 can be enhanced such that reliability failure such as wire disconnection in the heat cycle is unlikely to occur.

### Sixth Embodiment

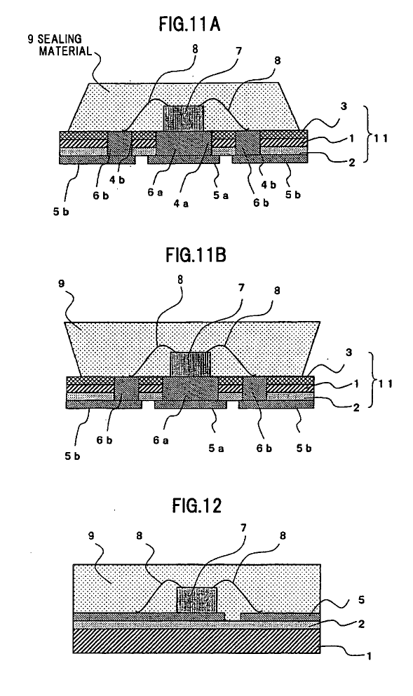

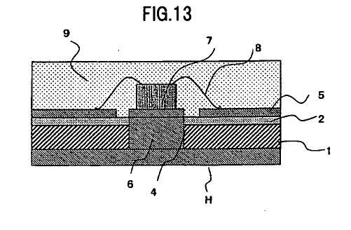

FIGS. 11A and 11B show another embodiment of the invention. The sixth embodiment is constructed such that, in the cross section of one LED package, the sealing material 9 is formed trapezoidal (See FIG. 10A) or inverted trapezoidal (See FIG. 10B). Before segmenting the LED module into an LED package, by cutting the sealing material 9 on the cutting lines for the segmentation, these forms can be obtained, whereby the cutting surface of the sealing material 9 can be prevented from being a fracture surface due to failure of the press-cutting. In addition, since there is substantially no sealing material 9 on the cutting lines when segmented, the cutting can be conducted without applying stress to the interface between the sealing material 9 and the electrical insulation material 11.

Further, when the wiring pattern such as the heat dissipation wiring pattern 5a and the feeding wiring pattern 5b as shown in FIG. 5B is combined with the electroless plating, only the electrical insulation material 11 can be cut without cutting the wiring pattern. Thereby, no metallic foreign matter occurs that may be generated in cutting the wiring pattern, whereby the life of the cutter used for the press-cutting can be elongated.

### Seventh Embodiment

Although not shown, in producing an LED module composed of three or more LED chips, the electrical connection of feeding wiring pattern may be made by suitably combining the serial connection and the parallel connection.

### Eighth Embodiment

Although not shown, the white insulation material composing the electrical insulation material may be a structure with two or more layers formed by suitably combining an organic white insulation material and an inorganic white insulation material. Furthermore, an adhesive material or primer layer may be formed between the base material and the white insulation material for enhancing the adhesion force.

### Other Embodiments

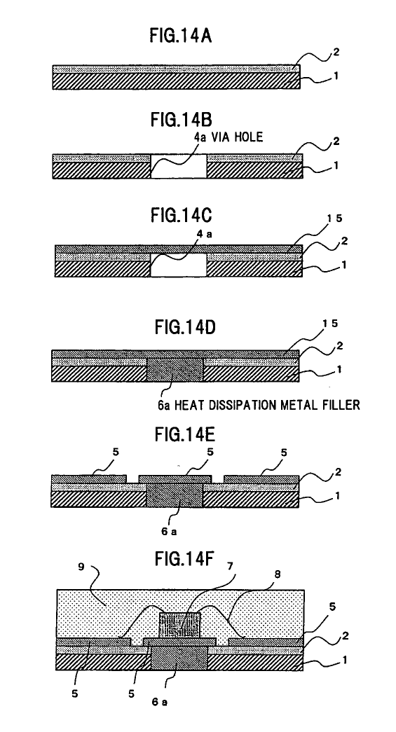

FIGS. 14A to 14E show a method of forming a buried plating in a TAB with a general single-sided wiring substrate. FIGS. 14A to 14E each are cross sectional views showing one unit of an LED module. First, the base material 1 with the adhesive layer 2 is provided (See FIG. 14A). Then, the via hole 4a is opened by punching (FIG. 14B). Then, the copper foil 15 is attached (See FIG. 14C), and the buried plating is formed in the via hole 4a to have the heat dissipation metal filler 6a (See FIG. 14D). Then, the copper foil 15 is patterned to form the wiring pattern 5 (See FIG. 14E). Then, if necessary, a plating is formed or a protecting film such as a resist is formed on the wiring pattern 5 (not shown). The LED chip 7 is mounted and wire-bonded with the wire 8 to produce the LED module (See FIG. 14F). In this embodiment, although the features of the first embodiment may not be included, it can be substantially expected that the heat dissipation metal filler 6a formed in the via hole 4a just under the LED chip 7 has the heat dissipation effect. The embodiment is an example of an LED module using the buried plating different from the invention.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. An LED module, comprising:
an electrical insulation material comprising a first surface having a total reflectivity of not less than 80% with respect to light with a wavelength of 450 nm;
a via hole penetrating through the electrical insulation material;
a wiring pattern on a second surface of the electrical insulation material;
a metal filler formed in the via hole and electrically connected to the wiring pattern; and
an LED chip bonded to a surface of the metal filler on the first surface of the electrical insulation material, and sealed with a resin.

2. The LED module according to claim 1, wherein the first surface of the electrical insulation material is white in color.

3. The LED module according to claim 1, wherein the electrical insulation material further comprises a white insulation material, a base material and an adhesive material, or a white base material and an adhesive material.

4. The LED module according to claim 3, wherein the base material or the white base material comprises one resin of polyimide, polyamide-imide, polyethylene-naphthalate, epoxy and aramid.

5. The LED module according to claim 3, wherein the base material or the white base material has a thickness of not less than 4 μm and not more than 75 μm.

6. The LED module according to claim 1, wherein the metal base material comprises a flat portion with a diameter of not less than 0.1 mm at a top thereof.

7. The LED module according to claim 1, wherein the metal base material is formed by copper electroplating.

8. The LED module according to claim 1, wherein the metal base material comprises a plating on a top thereof, and the plating comprises one of gold, silver, palladium, nickel and tin.

9. The LED module according to claim 1, wherein the metal base material comprises a protrusion from the first surface of the electrical insulation material, and the protrusion comprises a cross sectional portion greater than the via hole.

10. An LED package, comprising:
the LED module according to claim 1 and segmented in unit of one or more of the LED chip.

11. A wiring substrate, comprising:
an electrical insulation material comprising a first surface having a total reflectivity of not less than 80% with respect to light with a wavelength of 450 nm;
a via hole penetrating through the electrical insulation material;
a copper wiring pattern on a second surface of the electrical insulation material; and
a metal filler formed in the via hole and electrically connected to the wiring pattern,
wherein the metal filler is exposed from the electrical insulation material on the first surface of the electrical insulation material.

12. The wiring substrate according to claim 11, wherein the first surface of the electrical insulation material is white in color.

13. The wiring substrate according to claim 11, wherein the electrical insulation material further comprises a white insulation material, a base material and an adhesive material, or a white base material and an adhesive material.

14. The wiring substrate according to claim 13, wherein the base material or the white base material comprises one resin of polyimide, polyamide-imide, polyethylene-naphthalate, epoxy and aramid.

15. The wiring substrate according to claim 13, wherein the base material or the white base material has a thickness of not less than 4 μm and not more than 75 μm.

16. The wiring substrate according to claim 11, wherein the metal base material comprises a flat portion with a diameter of not less than 0.1 mm at a top thereof.

17. The wiring substrate according to claim 11, wherein the metal base material is formed by copper electroplating.

18. The wiring substrate according to claim 11, wherein the metal base material comprises a plating on a top thereof, and the plating comprises one of gold, silver, palladium, nickel and tin.

19. The wiring substrate according to claim 11, wherein the metal base material comprises a protrusion from the first surface of the electrical insulation material, and the protrusion comprises a cross sectional portion greater than the via hole.

20. A method of making the wiring substrate according to claim 11, comprising:
forming the via hole in the electrical insulation material;
laminating a metal foil on the second surface of the electrical insulation material; and
filling the metal filler in the via hole through the first surface of the electrical insulation material.
